(19) United States
(12) Patent Application Publication
(10) Pub. No.: US 2010/0006982 A1
(43) Pub. Date: Jan. 14, 2010

(54) METHOD OF PRODUCING SEMICONDUCTOR WAFER

(75) Inventors: Tomohiro Hashii, Tokyo (JP); Kazushige Takaishi, Tokyo (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: Sumco Corporation, Tokyo (JP)

(21) Appl. No.: 12/501,337

(22) Filed: Jul. 10, 2009

(30) Foreign Application Priority Data
Jul. 11, 2008 (JP) 2008-181102

(51) Int. Cl. H01L 23/58; B28D 1/02; B24B 1/00

(52) U.S. Cl. 257/618; 125/12; 451/41; 257/E23.002

(57) ABSTRACT

There is provided a method of producing a semiconductor wafer which is high in the beveling accuracy and the yield for large-size wafers having a diameter of not less than 450 mm, comprising a slicing step for cutting out a disc-shaped wafer having a diameter of not less than 450 mm from a single crystal ingot, a step for lapping a surface of the wafer to conduct planarization, a step for beveling an edge portion of the wafer, a step for grinding the surface of the wafer and a step for mirror-polishing the surface of the wafer, wherein the planarizing step performs the lapping with free abrasive grains of #1000 to #1500.

### BACKGROUND OF THE INVENTION

1. Field of the Invention

This invention relates to a method of producing a semiconductor wafer and, more particularly to a method of producing a mirror-finished semiconductor wafer by cutting out a disc-shaped wafer having a diameter of not less than 450 mm from a crystalline ingot.

2. Description of the Related Art

The conventional method of producing a semiconductor wafer generally comprises a slicing step for slicing a single crystal ingot pulled with a single crystal pulling apparatus to obtain a disc-shaped wafer, a beveling step for beveling an outer peripheral edge portion of the sliced wafer to prevent cracks or breakage of the sliced wafer, a lapping step for planarizing a surface of the beveled wafer, an etching step for removing a residual affected layer generated by beveling and lapping, a mirror polishing step for mirror-finishing a surface of the etched wafer and so on. For example, Patent Document 1 discloses the technique of sequentially conducting a slicing step, a surface grinding step, a beveling step and a polishing step.

As the planarizing step, there may be also adopted a technique wherein a wafer is planarized with a high accuracy through a grinding step using a surface grinding machine or a simultaneous double-sided surface grinding machine to reduce a variation or undulation in the thickness of the wafer in stead of the lapping step. As the surface grinding machine is generally known an infeed type surface grinding machine wherein a wafer is placed on a chuck table rotating at a high speed and a cup-type grinding stone is continuously cut into the wafer for grinding. Furthermore, as the simultaneous double-sided surface grinding machine are known a single wafer type double-sided surface grinding machine wherein a plurality of as-cut wafers are sequentially fed between an upper grinding stone and a lower grinding stone driving at a high speed while placing these wafers on a carrier driving at a low speed in a direction opposite to the driving direction of the grinding stones, a batch type double-sided surface grinding machine wherein upper and lower grinding stones are attached to the respective upper and lower platens and plural wafers placed in receiving holes of a carrier are interposed between the upper and lower grinding stones and then both surfaces of the plural wafers are simultaneously ground by the rotation of the lower platen and the pressurization through the upper platen, and so on.

In the conventional production method including Patent Document 1 or the like, it is common that a thin disc-shaped wafer is cut out from an ingot with a wire saw or a circular inner peripheral blade at the slicing step, and hence slight variation or undulation in thickness associated with the reciprocal motion of the wire may be caused in the wafer cut out with the wire saw. Also, there is a problem that such variation or undulation in thickness causes the scattering in the width of the beveled portion at the beveling step, deteriorating the yield of the product. Because, the beveling step is obliged to be conducted before the lapping step, that is, immediately after the slicing step, so that the wafer needs to be beveled during the large variation in thickness of the wafer.

Since the above problem remarkably appears in a large-size silicon wafer particularly having a diameter of not less than 450 mm, it is required to conduct further improvement in future.

[Patent Document 1] JP-A-H08-66850

### SUMMARY OF THE INVENTION

With the foregoing in mind, it is an object of the invention to provide a method of producing a semiconductor wafer which is high in the beveling accuracy and the yield for large-size wafers having a diameter of not less than 450 mm.

The inventors have made various studies on the production method of semiconductor wafers for solving the above problem.

As a result, it has been found that since the method comprises a slicing step for cutting out a disc-shaped wafer having a diameter of not less than 450 mm from a single crystal ingot, a step for lapping a surface of the wafer to conduct planarization, a step for beveling an edge portion of the wafer, a step for grinding the surface of the wafer and a step for mirror-polishing the surface of the wafer, the planarization by lapping is conducted before the beveling step to expect the improvement in the beveling accuracy but also it is possible to conduct the sufficient surface processing by using free abrasive grains of #1000 to #1500 at the planarizing step while ensuring the productivity.

The invention is based on the above knowledge and the summary and construction thereof are as follows:

(1) A method of producing a semiconductor wafer, which comprises a slicing step for cutting out a disc-shaped wafer having a diameter of not less than 450 mm from a single crystal ingot, a step for lapping a surface of the wafer to conduct planarization, a step for beveling an edge portion of the wafer, a step for grinding the surface of the wafer and a step for mirror-polishing the surface of the wafer, wherein the planarizing step performs the lapping with free abrasive grains of #1000 to #1500.

(2) The method of producing a semiconductor wafer according to the item (1), wherein the lapping, the grinding and the polishing are performed on both surfaces of the wafer.

(3) The method of producing a semiconductor wafer according to the item (2), wherein the free abrasive grains are Al₂O₃ or ZrO₂.

(4) A semiconductor wafer having a diameter of not less than 450 mm produced by using a production method of a semiconductor wafer as described in the item (1), (2) or (3), wherein a variation in a beveling width is not more than 10%.

According to the production method of the semiconductor wafer according to the invention, it is possible to provide a method of producing a semiconductor wafer which is high in the beveling accuracy and the yield for large-size wafers particularly having a diameter of not less than 450 mm.

### BRIEF DESCRIPTION OF THE DRAWING

The invention will be described with reference to the accompanying drawings, wherein:

FIG. 1 is a flow chart illustrating production steps of the invention; and

FIG. 2 is a schematic view for explaining a beveling width.

### DESCRIPTION OF THE PREFERRED EMBODIMENTS

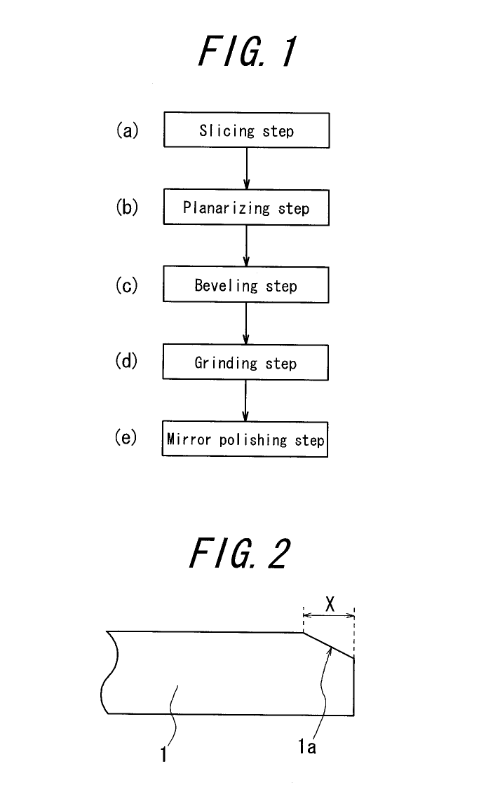

The production method of semiconductor wafers according to the invention will be described in detail with reference to the drawings. FIG. 1 is a flow chart illustrating steps according to an embodiment of the invention, wherein FIGS. 1(a) to (e) show each step, respectively.

The method of producing a semiconductor wafer according to the invention comprises a slicing step for cutting out a disc-shaped wafer having a diameter of not less than 450 mm from a single crystal ingot (FIG. 1(a)), a step for lapping the surface of the wafer to conduct planarization (FIG. 1(b)), a step for beveling the edge portion of the wafer (FIG. 1(c)), a step for grinding the surface of the wafer (FIG. 1(d)) and a step for mirror-polishing the surface of the wafer (FIG. 1(e)).

Next, each step in the method of producing a semiconductor wafer according to the invention will be explained.

(Slicing Step)

The slicing step of the invention (FIG. 1(a)) is a step of cutting out a disc-shaped wafer having a diameter of not less than 450 mm by contacting a wire saw with a crystalline ingot for cutting while feeding a grinding solution or by cutting a crystalline ingot with a circular inner peripheral blade. Moreover, the semiconductor wafer after the slicing step is preferable to be high in the flatness and small in the surface roughness as far as possible in order to reduce processing load in the subsequent planarizing step (FIG. 1 (b)). The crystalline ingot is typically a silicon single crystal ingot, but is not particularly limited thereto, and may be a silicon polycrystalline ingot for solar cells.

(Planarizing Step)

The planarizing step of the invention (FIG. 1(b)) is a step wherein the surface of the wafer cut out at the slicing step is lapped to improve the flatness of the wafer and to approach the wafer to a final thickness.

The planarizing step of the invention is characterized by lapping with free abrasive grains of #1000 to #1500. Since the beveling step (FIG. 1(c)) is conducted after the planarizing step, the beveling can be carried out on the wafer planarized by lapping to reduce the variation or undulation in thickness, and hence a wafer having a high beveling accuracy is obtained, but also useless beveling can be eliminated to improve the yield of the product.

Here, the reason why the free abrasive grains in a grinding solution used in the lapping is limited to a range of #1000 to #1500 is due to the fact that the sufficient surface processing becomes possible while maintaining the productivity.

Moreover, the conditions for the lapping are not particularly limited except for the use of free abrasive grains of #1000 to #1500, but may be, for example, usual conditions that the lapping can be conducted by applying a given grinding solution onto a platen made of cast iron and relatively moving the platen to the wafer. Also, the kind of the free abrasive grains is not particularly limited, but Al₂O₃, ZrO₂ or the like can be used.

Further, it is preferable that the lapping is performed on the both surfaces of the wafer. In this case, the undulations at both of the front and back surfaces can be removed, but also undulation in the slicing, which might not be solved only by planarizing based on the lapping of one-side surface, can be removed.

(Beveling Step)

The beveling step of the invention (FIG. 1(c)) is a step that an edge portion of the wafer lapped at the planarizing step is beveled by grinding and polishing.

The beveling method is not particularly limited, but the beveling can be conducted, for example, by using a grinding stone made of diamond having a roughness of about #800 to 2000.

Since the wafer has already been planarized by the given lapping at the planarizing step (FIG. 1(b)) before the beveling, the variation of the beveling width at the beveling step may be not more than 10%.

Here, the beveling width means a length X of a beveled portion 1a of the wafer 1 parallel to the surface of the wafer as shown in FIG. 2. When there is the undulation on the surface of the wafer 1 or when the thickness of the wafer 1 is different between the central portion and the edge portion, there is a fear that the beveling width X is changed to deteriorate the yield of the products, so that it is impossible to suppress the variation of the beveling width to not more than 10% with respect to large-size wafers having a diameter of 450 mm without using the production method of the invention.

Also, the beveled portion after the above beveling may be subjected to a polishing, if necessary, for further reducing the variation of the beveling width. For example, the beveled portion is polished by using a polishing cloth made from urethane or the like and feeding a polishing slurry. The kind of the polishing slurry is not particularly limited, but colloidal silica having a grain size of about 0.5 μm or the like can be used.

(Grinding Step)

The grinding step of the invention (FIG. 1(d)) is a step that the wafer after the above beveling step is subjected to a given grinding for setting the form of the wafer surface and the thickness of the wafer. The grinding is not particularly limited, and may be the same as used at the usual grinding step. For example, the grinding can be conducted by applying a given grinding solution onto a grinding pad made from a thermosetting resin and relatively moving the grinding pad to the wafer. Moreover, abrasive grains may be contained in the grinding solution or may be attached to the surface of the grinding pad. The kind thereof is also not particularly limited, but may include, for example, diamond, SiC and the like.

Moreover, the grinding is preferable to be performed on the both surfaces of the wafer. In this case, the undulations at both of the front and back surfaces can be removed, but also undulation in the slicing, which might not be solved only by planarizing one-side surface of the wafer, can be removed.

(Mirror Polishing Step)

The mirror-polishing step of the invention (FIG. 1(e)) is a step that the surface of the wafer is mirror-polished after the above grinding step. The polishing method is not particularly limited, and may be the same as used in the usual polishing step. For example, the polishing is conducted by applying a given polishing slurry onto a polishing cloth made from urethane or the like. The kind of the polishing slurry is not particularly limited, but it is preferable that colloidal silica having a grain size of not more than 0.5 μm is contained as abrasive grains.

Moreover, it is preferable that the polishing is performed on the both surfaces of the wafer, if necessary. For example, this is true when the lapping and the grinding are performed on the both surfaces of the wafer.

The reason why the diameter of the semiconductor wafer of the invention is limited to not less than 450 mm is due to the fact that when the production method according to the invention is applied to wafers having a diameter of not less than 450 mm, the effect of improving the beveling accuracy can be developed remarkably since wafers having a larger diameter are easily affected by the variation or undulation in thickness of the wafer and also the beveling width becomes large.

Although the above is described with respect to only one embodiment of the invention, various modifications may be made without departing from the scope of the appended claims.

A semiconductor wafer is trial-produced by the production method according to the invention, which will be descried below.

### EXAMPLE 1

A silicon wafer as a sample is produced according to the process flow of an embodiment of the invention shown in FIG. 1 by sequentially performing a slicing step for cutting out a disc-shaped wafer having a diameter of not less than 450 mm from a single crystal ingot (FIG. 1(a)), a step for lapping the both surfaces of the wafer to conduct planarization (FIG. 1(b)), a step for beveling the edge portion of the wafer (FIG. 1(c)), a step for grinding the both surfaces of the wafer (FIG. 1(d)) and a step for mirror-polishing the both surfaces of the wafer (FIG. 1(e)).

Moreover, the condition of the planarizing step is that the lapping is conducted by applying free abrasive grains having a roughness of about #1000 onto a platen made from cast iron.

### EXAMPLE 2

In Example 2, a silicon wafer as a sample is produced under the same conditions as in Example 1 except that the lapping, the grinding and the polishing are performed on one-side surface of the wafer.

### COMPARATIVE EXAMPLE 1

In Comparative Example 1, a silicon wafer as a sample is produced by the conventional production method, concretely by sequentially performing a slicing step, a beveling step, a grinding step, an etching step and a polishing step.

### COMPARATIVE EXAMPLE 2

In Comparative Example 2, a silicon wafer as a sample is produced under the same conditions as in Example 1 except that the roughness of free abrasive grains is #2000.

Various evaluations are conducted with respect to each sample of the above Examples and Comparative Examples.

(Variation of Beveling Width)

The evaluation of each sample is conducted by measuring a size of a beveling width (0.35 mm) of the wafer and calculating a difference (mm) between the minimum value and the maximum value relative to an average value (0.35 mm) of the beveling width as a variation (%).

(Flatness)

The flatness of each sample is measured with an electrostatic capacitance thickness sensor and evaluated as follows.
⊚: A flatness is less than 0.5 μm
◯: A flatness is not less than 0.5 μm but not more than 1 μm
X: A flatness exceeds 1 μm

The results evaluated on each sample are shown in Table 1.

TABLE 1

| | Variation in | |
|---|---|---|
| | beveling width (%) | Flatness |
| Example 1 | 5 | ⊚ |
| Example 2 | 10 | ◯ |
| Comparative Example 1 | 10 | X |
| Comparative Example 2 | 15 | X |

As seen from Table 1, the samples of Examples 1 and 2 are small in the variation of the beveling width and good in the flatness as compared with the samples of Comparative Examples 1 and 2.

According to the production method of the semiconductor wafer according to the invention, it is possible to provide a method of producing a semiconductor wafer which is high in the beveling accuracy and the yield for large-size wafers particularly having a diameter of not less than 450 mm.

1. A method of producing a semiconductor wafer, which comprises
a slicing step for cutting out a disc-shaped wafer having a diameter of not less than 450 mm from a single crystal ingot;
a step for lapping a surface of the wafer to conduct planarization;
a step for beveling an edge portion of the wafer;
a step for grinding the surface of the wafer; and
a step for mirror-polishing the surface of the wafer,
wherein the planarizing step performs the lapping with free abrasive grains of #1000 to #1500.

2. The method of producing a semiconductor wafer according to claim 1, wherein the lapping, the grinding and the polishing are performed on both surfaces of the wafer.

3. The method of producing a semiconductor wafer according to claim 2, wherein the free abrasive grains are Al₂O₃ or ZrO₂.

4. A semiconductor wafer having a diameter of not less than 450 mm produced by using a production method of a semiconductor wafer as claimed in claim 1, wherein a variation in a beveling width is not more than 10%.

5. The semiconductor wafer according to claim 4, wherein the lapping, the grinding and the polishing are performed on both surfaces of the wafer.

6. The semiconductor wafer according to claim 5, wherein the free abrasive grains are Al₂O₃ or ZrO₂.
